(19) United States
(12) Patent Application Publication
(10) Pub. No.: US 2008/0043449 A1
(43) Pub. Date: Feb. 21, 2008

(54) SYSTEMS AND METHODS FOR EXTERNAL ELECTRICAL COMPONENT INTERCONNECTION

(76) Inventor: Michael Pyle, Draper, UT (US)

Correspondence Address: BAKER & ASSOCIATES PLLC, 470 EAST NINTH AVENUE, SALT LAKE CITY, UT, 84103, US

(21) Appl. No.: 11/770,034

(22) Filed: Jun. 28, 2007

Related U.S. Application Data
(60) Provisional application No. 60/806,238, filed on Jun. 29, 2006.

(51) Int. Cl. H05K 1/11; H05K 5/02

(52) U.S. Cl. 361/752; 361/803; 439/65

(57) ABSTRACT

One embodiment relates to an encased electrical component board interconnection system, including an audio/video related electrical component board encased within a housing, an interconnection panel disposed on an external surface of the housing, and an interconnection retaining system. The electrical interconnection panel facilitates the electrical coupling between the electrical component board and external electrical devices. The interconnection panel includes electrical couplers disposed on independently oriented coupling surfaces. The coupling surfaces may be oriented in a convex outward facing configuration to facilitate efficient coupling and may further include an intermediary positioned labeling surface. The interconnection retaining system releasably supports an elongated interconnection device connected to the electrical couplers at a particular three-dimensional orientation that minimizes visual obstruction of the electrical interconnection panel and maintains proper electrical connection.

### RELATED APPLICATIONS

This application claims priority to U.S. provisional application Ser. No. 60/806,238 filed Jun. 29, 2006, the contents of which are incorporated by reference.

### FIELD OF THE INVENTION

The invention generally relates to systems and methods for electrical device interconnection and management. In particular, the invention relates to systems and methods for optimizing the interconnection of external electrical components.

### BACKGROUND OF THE INVENTION

Audio and video components are designed to convert electrical signals into either audio or video outputs in order to convey information to a user for purposes of entertainment or communication. For example, a television converts an electrical input signal into a visual image and a corresponding audible output. Improvements in technology have increased the performance of these devices so as to produce higher quality outputs. The quality of an audio or video output may be defined by the clarity or amount of undesirable signal present in the output. For example, a high quality audio output will include a minimal amount of audible noise such as static, crosstalk, etc.

Likewise, a high quality video image will include a minimal amount of visual noise such as stray images, color patterns, distortion, etc.

Home entertainment has evolved from separate audio and video components to integrated multi-component systems that are used to maximize performance. For example, audio systems are designed to produce a relatively high level of audio output for purposes of listening to music or other types of audio information. Whereas, video components typically include the ability to produce both audio and video outputs. However, the audio systems of most video components generally produce a lower quality output than a corresponding dedicated audio component. Therefore, components have been developed to couple with one another so as to increase performance or provide additional functionality. Various components are commonly electrically coupled together including video output devices, audio output devices, video input devices, audio input devices, networking devices, etc.

Modem presentations utilize audio and visual information to assist in communicating concepts in an effective and efficient manner. For example, presenters often utilize Powerpoint™ presentations to include visual information that assists in communicating concepts during a presentation. Presentations may also include media clips or audio recordings. As with home entertainment, higher quality audio and video is preferable to effectively convey concepts or entertain an audience during presentations.

The performance, reliability, and/or quality level of audio and video components is affected by a multitude of variables and characteristics. Advances in electrical technology alone do not necessarily solve certain performance problems with respect to audio and video components. For example, the quality of video produced by a video output component will be significantly affected by a power supply that includes an abundance of electrical abnormalities regardless of the video technology included in the particular video output device. It is also necessary for components to operate and intercouple with one another in a simplified, seamless and reliable manner so as to be utilized to the full potential. Therefore, there is a need in the industry for systems and methods of increasing audio and video performance by incorporating technologies that maximize performance characteristics. In addition, there is a need in the industry for systems and methods that allow users to more effectively utilize audio and video components, including integration, interfaces, and operational systems.

### SUMMARY OF THE INVENTION

Embodiments of the present invention relate to systems and methods for electrical interconnection. One embodiment relates to an encased electrical component board interconnection system, including an audio/video related electrical component board encased within a housing, an interconnection panel disposed on an external surface of the housing, and an interconnection retaining system. The electrical interconnection panel facilitates the electrical coupling between the electrical component board and external electrical devices. The interconnection panel includes electrical couplers disposed on independently oriented coupling surfaces. The coupling surfaces may be oriented in a convex outward facing configuration to facilitate efficient coupling and may further include an intermediary positioned labeling surface. The interconnection retaining system releasably supports an elongated interconnection device connected to the electrical couplers at a particular three-dimensional orientation that minimizes visual obstruction of the electrical interconnection panel and maintains proper electrical connection. A second embodiment relates to a method for electrically coupling an encased electrical component board with an external electrical device.

Conventional audio and video systems often include a plurality of electrical couplers for coupling with other components and devices. However, these couplers are often closely spaced to one another and positioned on the back of a device. By positioning these couplers in close proximity to one another, it is difficult to visually organize and manage interconnections. Likewise, conventional systems are often organized horizontally, thereby forcing connection systems to overlap one another. In addition, users often position these devices against a flat vertical surface, which may cause the electrical interconnections to short circuit. Systems and methods of the present invention overcome these problems through the use of novel coupling surface orientation and retention systems.

These and other features and advantages of the present invention will be set forth or will become more fully apparent in the description that follows and in the appended claims. The features and advantages may be realized and obtained by means of the instruments and combinations particularly pointed out in the appended claims. Furthermore, the features and advantages of the invention may be learned by the practice of the invention or will be obvious from the description, as set forth hereinafter.

### BRIEF DESCRIPTION OF THE DRAWINGS

The following description of the invention can be understood in light of the Figures, which illustrate specific aspects of the invention and are a part of the specification. Together with the following description, the Figures demonstrate and explain the principles of the invention. The Figures presented in conjunction with this description are views of only particular—rather than complete—portions of the systems and methods of making and using the system according to the invention. In the Figures, the physical dimensions may be exaggerated for clarity. The figure numbers corresponded to the respective page number.

FIG. 1 illustrates an exploded perspective view of an encased electrical component board system including one embodiment of the present invention;

FIG. 2 illustrates a perspective view of an encased electrical component board interconnection system in accordance with the embodiment illustrated in FIG. 1;

FIG. 3 illustrates a front view of the interconnection panel illustrated in FIG. 1;

FIG. 4 illustrates a profile view of the interconnection panel illustrated in FIG. 1; and

FIG. 5 illustrates a top view of the interconnection panel illustrated in FIG. 1.

### DETAILED DESCRIPTION OF THE INVENTION

Embodiments of the present invention relate to systems and methods for electrical interconnection. One embodiment relates to an encased electrical component board interconnection system, including an audio/video related electrical component board encased within a housing, an interconnection panel disposed on an external surface of the housing, and an interconnection retaining system. The electrical interconnection panel facilitates the electrical coupling between the electrical component board and external electrical devices. The interconnection panel includes electrical couplers disposed on independently oriented coupling surfaces. The coupling surfaces may be oriented in a convex outward facing configuration to facilitate efficient coupling and may further include an intermediary positioned labeling surface. The interconnection retaining system releasably supports an elongated interconnection device connected to the electrical couplers at a particular three-dimensional orientation that minimizes visual obstruction of the electrical interconnection panel and maintains proper electrical connection. A second embodiment relates to a method for electrically coupling an encased electrical component board with an external electrical device. Also, while embodiments of the present invention are described in the context of electrical interconnection systems for audio an video components, it will be appreciated that the teachings of the present invention are applicable to other areas.

The following terms are defined for purposes of utilization throughout this application:

Electrical component board—A board configured to house a plurality of electrical components, wherein the electrical components are mechanically coupled to the board and electrically coupled to one another. In addition, electrical component boards may mechanically and electrically couple with a bus or receiver unit to facilitate support. An electrical component board may include a mounting structure for normalizing the size of multiple standard printed circuit boards (PCB).

Vertical alignment—A device that is vertically aligned or positioned such that its longest dimension is oriented in a substantially vertical plane or normal to a supporting surface. For example, a telephone pole is aligned vertically.

Plenum—A module for redirecting air flow. In the illustrated embodiments, the plenum is disposed below the electrical component boards.

Audio input device—An electrical device configured to produce audio signals including but not limited to a receiver, tuner, digital media player (CD, DVD, etc.), television, computer, gaming console, portable media player, etc.

Audio output device—An electrical device configured to receive and broadcast audio signals in an audible format, including but not limited to speakers, subwoofers, tweeters, headphones, etc.

Video input device—An electrical device configured to produce video signals including but not limited to a cable receiver, tuner, television, computer, gaming console, etc.

Video output device—An electrical device configured to receive and broadcast video signals in a visual format, including but not limited to a monitor, television, cell phone, portable media player, etc.

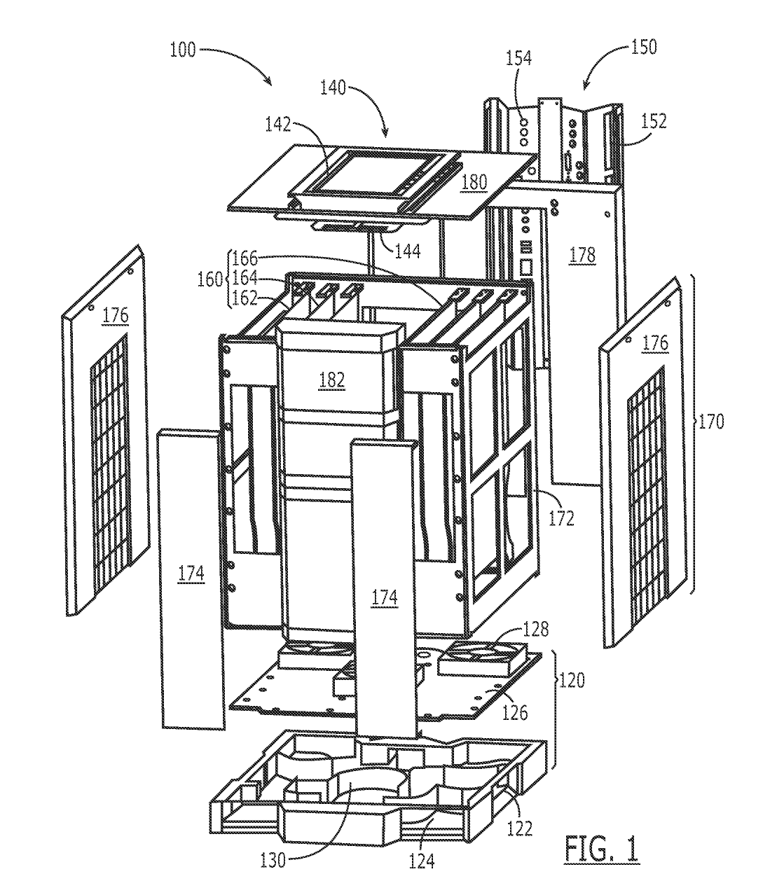

Reference is initially made to FIG. 1, which illustrates an exploded perspective view of an encased electrical component board system incorporating one embodiment of the present invention, designated generally at 100. The illustrated system also contains a particular cooling system, which will be described briefly below for reference purposes. The vertical nature of the illustrated system 100 affects the orientation of the associated interconnection panel 150. The system 100 includes a set of electrical component boards 160, a plenum 120, an outlet 140, and a housing 170. The illustrated electrical component boards 160 include six boards, three of which are designated respectively as a first, second, and fourth board 162, 164, 166. Various systems may hold as few as two electrical component boards and still incorporate the teachings of the present invention. The illustrated electrical component boards 160 include individual electrical components electrically intercoupled as a conventional printed circuit board to provide audio and/or video functionalities. Each of the electrical component boards 160 may be a conventional audio or video component without its housing, such as a DVD player, game console, DVR, etc. The electrical component boards 160 are also electrically intercoupled with one another to further provide audio and/or video functionalities. The electrical intercoupling of the individual electrical component boards 160 is configured to integrate their functionalities and includes both software and hardware integration. To facilitate the proper air flow, the electrical component boards 160 are oriented vertically with the longest axis oriented perpendicular to the supporting surface. The orientation of the boards 160 is mechanically supported by the housing 170 and more particularly by an internal chassis or racking system 172. The electrical component boards 160 may further include mounting structures so as to ensure consistent shaping among the individual boards. The internal chassis or racking system creates a particular spacing between the boards as illustrated.

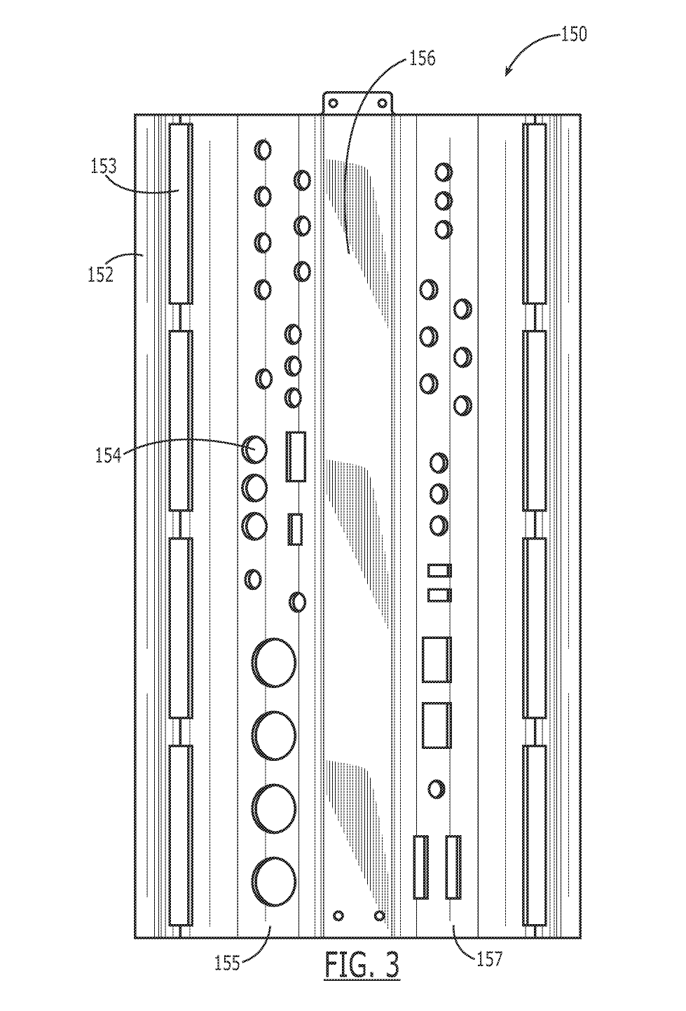

The plenum 120 is disposed below the housing 170 and the electrical component boards 160. The plenum 120 facilitates the intake and directing of ambient air for the cooling system 100. The plenum 120 includes a front inlet 124, a lateral inlet 122, a set of air guides 130, a cover 126, and a set of fans 128. The inlets 122, 124 receive ambient air from the surrounding environment and allow it to enter the system at a location vertically below the electrical component boards 160. This location of air intake is critical for the overall system's ability to utilize the natural process of convection for heat transfer. The set of air guides 130 and cover 126 create independent air flow channels that horizontally direct air flow to regions vertically aligned between the individual electrical component boards 160. In the illustrated embodiment, these vertically aligned locations correspond to the positioning of the fans 128. It should be noted that the fans 128 enhance the natural convectional based air flow and are optional components. Therefore, even if the fans 128 are removed or malfunction, the system 100 will circulate ambient air through convection alone. In the illustrated embodiment, the fans 128 enhance the air flow by further directing the air vertically from the plenum 120 between the electrical component boards 160. Additional details and description of the plenum 120 and its associated-system wide functionality and internal technology will be discussed in reference to FIGS. 3A-3B.

The housing 170 substantially encases and supports the electrical component boards 160 in the vertically oriented configuration illustrated and described above. The region within the housing 170 receives air flow vertically from the plenum 120, allowing it to flow vertically around and between the electrical component boards 160 and then exhaust toward the outlet 140. The air flow adjacent to the electrical component boards

The housing 170 includes a plurality of panels, a set of front panels 174, a set of side panels 176, a rear panel 178, and a top panel 180. The housing 170 further includes an internal chassis 172, a front console 182, and a rear connection panel 150. The panels 174, 176, 178, 180 mechanically couple to one another and the internal chassis 172 to define an internal region in which the electrical component boards 160 are housed. The encasement of electrical components is well used in the electronics industry for purposes such as dust protection, electrical isolation, and noise dampening. The front console 182 includes various electrical interconnections, human interface modules, and remote control transceiver locations. The interconnection panel 150 provides a plurality of electrical connections for input and output to the electrical component boards 160. The interconnection panel includes a retaining member 152 and a set of electrical couplers 154.

The outlet 140 is disposed on the top cover 180 of the housing 170 to facilitate the exhaust of the temperature affected air through convectional heat transfer principles. The outlet 140 is disposed above the electrical component boards 160 and at the apex of the system 100 to enable heated air to naturally rise away from the electrical component boards 160 and exhaust out of the system 100. The outlet 140 includes an internal baffle 144 and an external port 142. The temperature affected air from within the housing will flow both horizontally and vertically around the baffle 144 and out through the external port 144 so as to be recombined with the ambient air, thereby creating an air flow cycle.

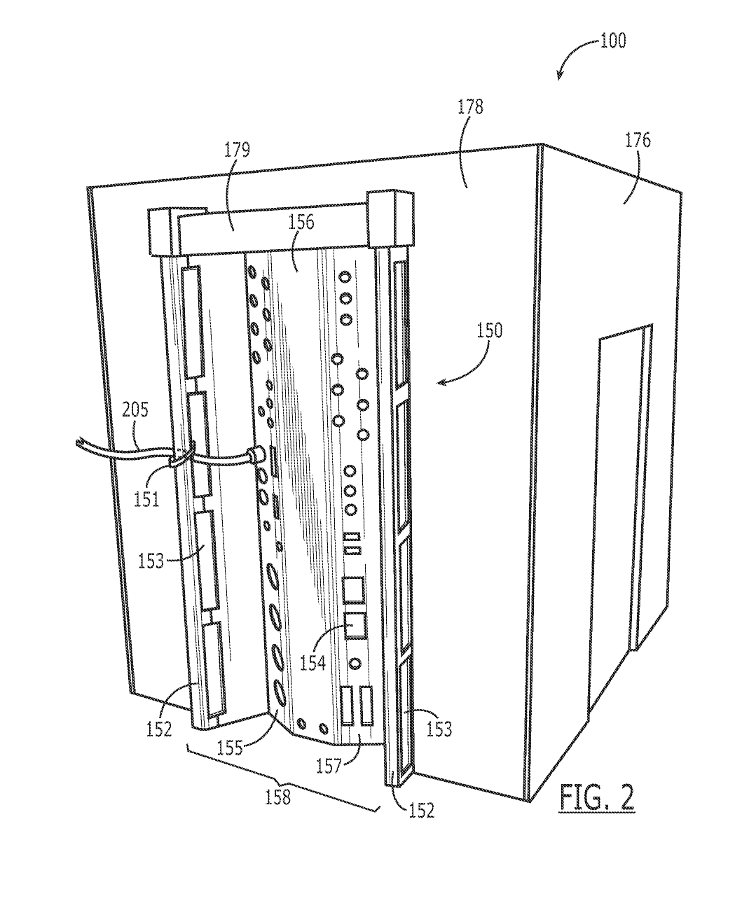

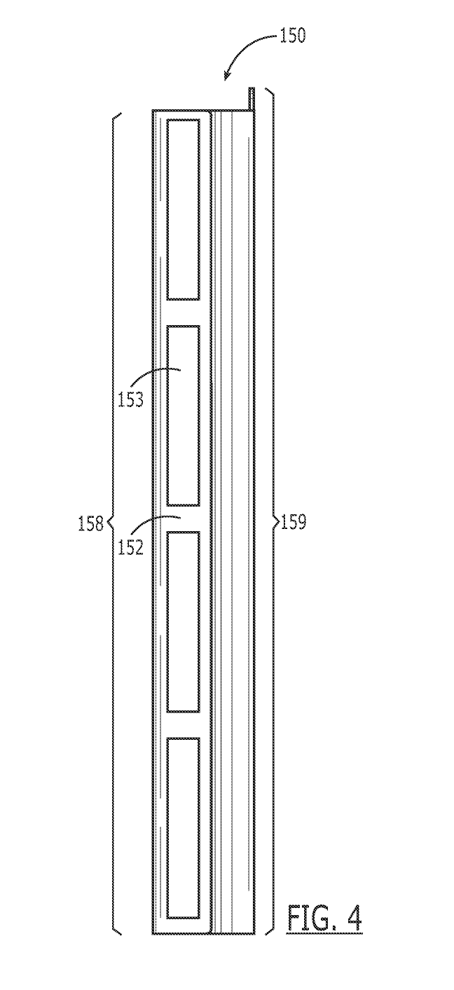

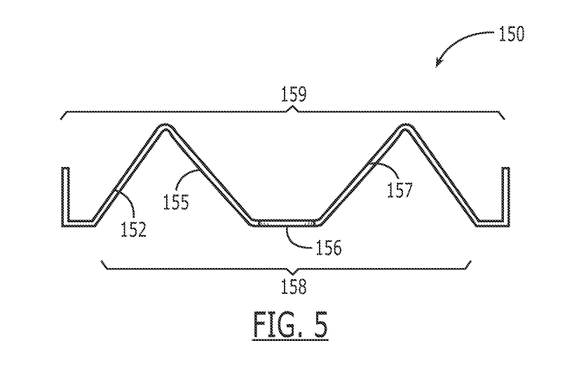

Reference is next made to FIGS. 2-5, which illustrate views of an interconnection panel, designated generally at 150. The interconnection panel 150 is positioned within a rear vertical surface of the system 100 to facilitate electrical interconnection with external devices. For example, an audio output of the system 100 may be coupled via the interconnection panel 150 to one or more speakers for audible signal translation. In particular, the interconnection panel 150 is disposed within the rear panel 178 and under a rear panel hood 179 of the housing 170 so as to access the electrical component boards 160. The interconnection panel 150 includes a first coupling surface 155, a labeling surface 156, a second coupling surface 157, a set of electrical couplers 154, a pair or retaining members 152, and a set of retaining recesses 153. For contextual purposes, it will be noted that FIGS. 2 and 3 illustrate the front surface 158 of the interconnection panel 150 and FIGS. 4 and 5 illustrate both the front and rear surfaces 158, 159 of the interconnection panel. The overall cross-sectional shape of the interconnection panel 150 is substantially W-shaped (see FIG. 5) including the corresponding positioning of the coupling surfaces 155, 157 on the inner outward facing portions of the W-shape and the coupling members 152 on the outer portions of the W-shape. The positioning of the labeling surface 156 is not represented by the W-shape but would be positioned between the inner portions.

The electrical couplers 154 are disposed on the first and second coupling surfaces 155, 157 as illustrated. The electrical couplers 154 provide standardized coupling mechanism to facilitate electrical coupling between external electrical devices and the electrical component boards 160. For example, RCA, USB, Coax, HDMI, VGA, etc. are standard connection schemes that include particular couplers. The electrical couplers 154 include both input type and output type couplers. Input type electrical couplers refer to electrical connections between an external electrical device and the electrical component boards 160 which relate to data being transmitted to the electrical component boards 160. Whereas, output type electrical couplers refer to electrical connections in which data is transmitted to the external electrical device. In the illustrated embodiment, the input-type electrical couplers 154 are positioned on the first coupling surface 155 and the output-type electrical couplers 154 are positioned on the second coupling surface 157. This relative positioning facilitates intuitive user operation and minimizes potential electrical interference between dissimilar input and output type connections.

The first and second coupling surfaces 155, 157 are vertically oriented parallel to one another and positioned on opposite vertical sides of the labeling surface 156. The labeling surface 156 is horizontally oriented parallel to the rear panel 178 of the housing 170. The first and second coupling surfaces 155, 157 are horizontally oriented to be outward facing or convex of one another. This outward/convex orientation of the front surfaces 158 of the coupling surfaces 155, 157 is best illustrated in FIG. 5. For purposes of this application, the term horizontally oriented refers to the cross-sectional horizontal orientation illustrated in the associated figures. The convex orientation is further defined as orienting the external surfaces to be more than 180 degrees apart. The outward orientation of the coupling surfaces 155, 157 facilitates efficient interconnection of the electrical couplers 154. Conventional systems generally orient all electrical couplers on a parallel surface causing overlap and potential mechanical and electrical interference. The coupling surfaces' 155, 157 relative outward/convex orientation minimizes overlap by directing associated elongated couplers away from one another. The labeling surface 156 is horizontally positioned between the coupling surfaces 155, 157 to facilitate separation of the coupling surfaces 155, 157 and visual labeling of the relative electrical couplers 154. The labeling surface 156 is vertically oriented to correspond to the coupling surfaces 155, 157. Various visual labeling schemes and labeling surface 156 positions may be utilized in conjunction with embodiments of the present invention.

The retaining members 152 are disposed on the outer horizontal lateral sides of the coupling surfaces 155, 157 as illustrated. The retaining members 152 include a surface that is substantially orthogonal to the coupling surfaces 155, 157. The retaining recesses 153 are vertically positioned along the retaining members 152 and extend horizontally through the retaining members 152 to create the slotted vertical profile illustrated in FIG. 4. The relative size of the retaining recesses 153 is specifically selected to accommodate the necessary electrical connectors corresponding to the electrical couplers 154. The orientation and size of the retaining recesses 153 with respect to the coupling surfaces 155, 157 enable elongated coupling devices 205 to be routed laterally through the retaining recesses 153 and optionally three dimensionally supported by a releasable coupler 151 as shown in FIG. 2. The releasable coupler 151 may be any type of releasable coupler 151 including but not limited to a VELCRO band, nylon strap, string, etc. The releasable coupler 151 preferably does not include conductive components so as to minimize the potential electrical affects upon corresponding elongated electrical connectors 205. By directing and routing elongated coupling devices 205 laterally through the retaining recesses 153, overlap among the elongated coupling devices 205 is minimized. As discussed above, overlap of elongated coupling devices can cause both mechanical and electrical problems including data corruption, short circuiting, inductance, capacitance, cross-talk, etc. The elongated coupling devices 205 include but are not limited to wires, fibers, cables, pipes, etc. Most elongated coupling devices 205 are in part flexible to facilitate a particular bending angle across a particular elongated distance. However, this bending angle is significantly less than 90 degrees in under three inches and therefore it is not generally possible for conventional electrical coupling schemes to laterally direct elongated electrical couplers away from the location of electrical coupling without risk of damage to the integrity of the electrical connection. The orientation of the retaining members 152 and retaining recesses 153 with respect to the coupling surfaces 155, 157 enables the desired direct lateral positioning.

Alternatively, the elongated electrical connectors 205 may be routed as a group vertically downward. In this alternative configuration, various releasable couplers 151 may still be required to efficiently route the elongated electrical connectors 205 along the outer portion of the retaining members 152 so as to prevent mechanical and electrical interference. This implementation may be particularly useful in aesthetically routing the group of cables to a particular external location.

In addition, it will be noted that the coupling surfaces 155, 157 are in part recessed within the rear panel 178 of the housing 170 while the retaining members 152 extend out from the rear panel 178. This partial recession in conjunction with the relative positioning of the retaining recesses 153 and coupling surfaces 155, 157 creates the necessary depth for the elongated coupling devices 205 to be housed within the depth of the interconnection panel 150. This concept of electrical connection depth containment is best illustrated in FIG. 5. By containing the depth of the elongated coupling devices 205, it is possible to allow the system 100 to be positioned substantially flush against a rear wall or surface without compromising the integrity of the electrical couplings. This positioning also facilitates an enhanced visual appearance of the system by minimizing the appearance of the elongated coupling devices 205. An optional rear cover (not shown) could therefore be vertically positioned between the retaining members 152, effectively visually containing the coupling surfaces 155, 157, electrical couplers 154, and a portion of the elongated coupling device(s) 205. The remaining visually apparent portion of the elongated coupling device(s) 205 would be extended laterally from the retaining members 152.

Various other embodiments have been contemplated, including combinations in whole or in part of the embodiments described above.

What is claimed is:

1. An encased electrical component board interconnection system comprising:
an electrical component board substantially encased within an interior region of a housing;
an interconnection panel disposed on an external surface of the housing such that a rear surface is exposed to the interior region and a front surface is externally exposed, and wherein the interconnection panel is configured to facilitate a plurality of independent electrical couplings between an external electrical device and the electrical component board, wherein the interconnection panel includes:
a plurality of independently oriented coupling surfaces;
a plurality of electrical couplers disposed on the coupling surfaces, wherein the electrical couplers are electrically coupled to the electrical component board; and
a retaining system configured to releasably support elongated interconnection devices coupled to one of the plurality of electrical couplers at a particular three dimensional orientation, wherein the elongated interconnection devices are electrically coupled to the external electrical devices.

2. The system of claim 1, wherein the interconnection panel further includes a labeling surface disposed between two of the independently oriented coupling surfaces.

3. The system of claim 1, wherein the exterior of the coupling surfaces are oriented more than 180 degrees from one another.

4. The system of claim 1, wherein the electrical component board includes at least one of an audio input, video input, audio output, and video output type functionality.

5. The system of claim 1, wherein the exterior of the coupling surfaces are oriented in a parallel vertical configuration, and an exterior convex horizontal configuration with respect to one another.

6. The system of claim 1, wherein the electrical couplers include a set of electrical input couplers and a set of electrical output couplers, and wherein the electrical input couplers are disposed on an independent coupling surface with respect to the electrical output couplers.

7. The system of claim 1, wherein the interconnection panel forms a substantially W-shaped horizontal cross-sectional configuration in which the coupling surfaces are disposed on two of the four surfaces.

8. The system of claim 1, wherein the retaining system includes a plurality of retaining members and retaining recesses independently disposed adjacent to the respective coupling surfaces.

9. The system of claim 8, wherein the retaining members and retaining recesses are externally horizontally oriented to include a surface concave with respect to the corresponding adjacent coupling surface.

10. The system of claim 8, wherein the retaining recesses are disposed lengthwise along the retaining members to create a slotted surface.

11. The system of claim 8, wherein the retaining system further includes a releasable strap coupler configured to extend through the retaining recess and releasably couple with the elongated interconnection device.

12. The system of claim 11, wherein the releasable strap coupler includes a VELCRO attachment system.

13. The system of claim 8, wherein the retaining members and retaining recesses are oriented vertically parallel and horizontally orthogonal to the corresponding adjacent coupling surface.

14. An electrical component interconnection system comprising:
an electrical component board substantially encased within an interior region of a housing;
an interconnection panel disposed on an external surface of the housing such that a rear surface is exposed to the interior region and a front surface is externally exposed, and wherein the interconnection panel is configured to facilitate a plurality of independent electrical couplings between an external electrical device and the electrical component board, wherein the interconnection panel includes:
a plurality of independently oriented coupling surfaces, wherein the exterior of the coupling surfaces are oriented in a parallel vertical configuration, and an exterior convex horizontal configuration with respect to one another;
a plurality of electrical couplers disposed on the coupling surfaces, wherein the electrical couplers are electrically coupled to the electrical component board; and
a retaining system configured to releasably support elongated interconnection devices coupled to one of the plurality of electrical couplers at a particular three dimensional orientation, wherein the elongated interconnection devices are electrically coupled to the external electrical devices, wherein the retaining system includes a plurality of retaining members and retaining recesses independently disposed adjacent to the respective coupling surfaces.

15. A method for electrically coupling an encased electrical component board with an external electrical device comprising the acts of:
providing an electrical component board substantially encased within an interior region of a housing;
providing a plurality of coupling surfaces on an exterior surface of the housing, wherein the coupling surfaces are externally convex with respect to one another;
electrically coupling the electrical component board to an external electrical device via an electrical coupler disposed on one of the coupling surfaces and an elongated interconnection device extending between the electrical coupler and the external electrical device; and
three-dimensionally supporting the elongated interconnection device with respect to the corresponding coupling surface and electrical coupler.

16. The method of claim 15, wherein the act of providing a plurality of coupling surfaces on an exterior surface of the housing includes vertically orienting the longest axis of the coupling surfaces parallel to one another.

17. The method of claim 15, wherein the act of providing a plurality of coupling surfaces on an exterior surface of the housing includes providing a labeling surface between two of the coupling surfaces.

18. The method of claim 15, wherein the act of electrically coupling the electrical component board to an external electrical device via an electrical coupler disposed on one of the coupling surfaces and an elongated interconnection device extending between the electrical coupler and the external electrical device includes:
electrically coupling the electrical coupler to the electrical component board; and
electrically engaging the elongated interconnection device with the electrical coupler.

19. The method of claim 15, wherein the act of three-dimensionally supporting the elongated interconnection device with respect to the corresponding coupling surface and electrical coupler includes:
providing a retaining member and retaining recess disposed adjacent to the corresponding coupling surface, wherein the retaining recess is disposed on the retaining member;
extending a releasable coupler through the retaining recess and around the elongated interconnection device; and
releasably coupling the releasable coupler to itself.

20. The method of claim 19, wherein the act of releasably coupling the releasably coupler to itself includes threading the releasable coupler through itself.
